(19) United States
(12) Patent Application Publication
(10) Pub. No.: US 2006/0042685 A1
(43) Pub. Date: Mar. 2, 2006

(54) Electronic devices having a charge transport layer that has defined triplet energy level

(76) Inventor: Ying Wang, Wilmington, DE (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/925,764

(22) Filed: Aug. 25, 2004

(51) Int. Cl. H01L 31/00

(52) U.S. Cl. 136/256; 136/252

(57) ABSTRACT

Electronic devices including a layer that contains a photoactive material, wherein an excited state of the photoactive material has an excitation energy Eₑₓ and wherein the photoactive material is either: (1) not a guest in a composition including a host, or (2) is a guest in a composition including a guest and a host, with the proviso that an electronic transport material is not included in the composition having the the guest and the host; and a charge transport layer located between the electrode and the photoactive layer, wherein the charge transport material has a triplet energy level that is higher than Eₑₓ. Alternatively, the layer includes a composition having the photoactive material as a guest, a host, and an electron charge transport material, and the device has two charge transport layers wherein both charge transport layers include a material having a triplet energy level that is higher than Eₑₓ.

### FIELD OF THE INVENTION

This invention relates to organic electronic devices having both photoactive and charge transport layers.

### BACKGROUND INFORMATION

Organic electronic devices, such as organic light-emitting diodes (OLEDs) used in display devices, are well known and currently used in many different kinds of electronic equipment. In these devices, a layer containing photoactive material is sandwiched between two electrical contact layers. In the OLED, the electrical contact layers generate positively-charged holes and negatively charged electrons, which combine in the photoactive layer and cause photon generation. In an OLED, at least one of the electrical contact layers is transparent or translucent so that the generated photons can pass through the electrical contact layer and escape the device. The recombining of holes and electrons plays a roled in the performance of other organic electronic devices as well.

On a molecular level, the combination of holes and electrons results in either the triplet or the singlet spin arrangement for the electrons in the excited state of the luminescent layer. If the combination of electrons and holes is statistically controlled, 25% of the combination would result in generation of pure singlet states and 75% would result in pure triplet states. Thus, devices that generate light based on a triplet mechanism (i.e., phosphorescent devices) have a theoretical electroluminescence efficiency four times larger than that of devices that generate light based on singlet state luminescence (i.e., fluorescent devices). Unfortunately, the triplet state of organic molecules usually have low radiative rate (and thus a low luminescence efficiency) and a long lifetime. The low radiative rate and lifetime make the triplet state-based devices unsuitable for display applications.

In OLEDs, in order to take advantage of the high theoretical efficiency of phosphorescent devices, organometallic compounds containing heavy elements with strong spin-orbit coupling efficiency are used in the luminescent layer. Use of these molecules helps overcome obstacles that have made designing efficient phosphorescent devices difficult, such as low radiative rate and long lifetime. The metal-mediated luminescent states of these organometallic compounds (frequently referred to as the metal-to-ligand-charge-transfer (MLCT) state) generally have strongly mixed singlet and triplet character, and this mixed character is responsible for the high yield of the luminescent state from electron-hole combination. Moreover, the metal-mediated state increases the radiative rate by several orders of magnitude compared to the pure triplet state, thus allowing high luminescence efficiency. OLED devices based on metal-mediated luminescent state thus combine the desirable qualities of both the phosphorescent and fluorescent OLED devices.

In OLEDs, the luminescent lifetime of a metal-mediated state in these organometallic luminescent compounds is in the sub-microseconds to microseconds range. Although this is short relative to the milliseconds-seconds lifetime range of the triplet state, it is long relative to the typical nanoseconds to picoseconds lifetime of the singlet state. Because of this long lifetime, the electroluminescence efficiency of devices built with these materials is very sensitive to the composition of the charge transport materials in the adjacent layers.

Effective hole/electron combination is important to other devices employing photoactive materials. In order to take advantage of the high-efficiency of metal-mediated states, devices with suitable charge transport materials have to be used for device construction. Criteria for selecting such charge transport materials and for constructing high efficiency devices are described.

Skilled artisans appreciate that elements in the figures are illustrated for simplicity and clarity and have not necessarily been drawn to scale. For example, the dimensions of some of the elements in the figures may be exaggerated relative to other elements to help to improve understanding of the embodiments of the invention.

### SUMMARY OF THE INVENTION

Provided is an electronic device including an electrode, a layer that contains photoactive material, wherein an excited state of the photoactive material has an excitation energy Eₑₓ and wherein the photoactive material is either: (1) not a guest in a composition including a host, or (2) is a guest in a composition including a guest and a host, with the proviso that an electronic transport material is not included in the composition including the guest and the host; and a charge transport layer located between the electrode and the photoactive layer, wherein the charge transport material has a triplet energy level that is higher than Eₑₓ.

Another embodiment is a device including a layer that has a photoactive material, wherein an excited state of the photoactive material has an excitation energy Eₑₓ and wherein the photoactive material is a guest in a composition including the photoactive material, a host, and an electron charge transport material; and the device further includes at least one hole transport layer and at least one electron transport layer, wherein a hole transport material and an electron transport material each, respectively, has a triplet energy level that is higher than Eₑₓ.

Also provided is method for selecting the charge transport material for delivering charges to a photoactive material so that high-efficiency devices can be realized. The method includes determining an excited state energy Eₑₓ possessed by the photoactive material; and selecting the charge transport material based on having a triplet energy level greater than Eₑₓ.

The foregoing is a general description and the following detailed description are exemplary and explanatory only and are not restrictive of the invention as defined in the appended claims.

### BRIEF DESCRIPTION OF THE DRAWINGS

The invention is illustrated by way of example and not limited to the accompanying figures.

FIG. 1 is a side view of an electric device that may be built using a triplet-energy-based charge transport material selection method.

### DETAILED DESCRIPTION

Provided is an electronic device including an electrode, a layer that contains photoactive material, wherein an excited state of the photoactive material has an excitation energy Eₑₓ and wherein the photoactive material is either: (1) not a guest in a composition including a host, or (2) is a guest in a composition including a guest and a host, with the proviso that an electronic transport material is not included in the composition including the guest and the host; and a charge transport layer located between the electrode and the photoactive layer, wherein the charge transport material has a triplet energy level that is higher than Eₑₓ.

In another embodiment, the electronic device includes a layer that includes a photoactive material, wherein an excited state of the photoactive material has an excitation energy Eₑₓ and wherein the photoactive material is a guest in a composition including the photoactive material, a host, and an electron charge transport material; and, the device further includes at least one hole transport layer and at least one electron transport layer, wherein a hole transport material and an electron transport material each has a triplet energy level that is higher than Eₑₓ.

In one embodiment, a charge transport material is selected from any charge transport materials. In one embodiment, the hole transport material has a high mobility for holes (positive charges), >10⁻⁶ cm²/V/sec at the operating voltage. In one embodiment, the hole transport material is selected such that its highest occupied molecular orbital (“HOMO”) levels or ionization potential so as to create a low barrier to hole injection from the anode. In general the ionization potential (HOMO related) and electron affinity (LUMO related) are known or can determined by known techniques. In one embodiment, the host is also capable of transporting electrons, with a mobility >10⁻⁷ cm²/V/sec at the operating voltage.

The electron transport material may be selected from any of the known electron transport materials. In one embodiment, the electron transport material has a high mobility for electrons, >10⁻⁸ cm²/V/sec at the operating voltage. In one embodiment, the electron transport material is selected such that its lowest un-occupied molecular orbital (“LUMO”) levels or electron create a low barrier to electron injection from the cathode.

A “charge transport layer” is a layer comprising a charge transport material. As used herein, the term “charge transport material,” is intended to mean a material that can receive a charge and facilitate its movement through the thickness of the material with relatively high efficiency and small loss of charge. The term is broad enough to hole and electron transport materials and hole and electron injection materials.

A “hole transport material” is a type of charge transport material that can receive and facilitate the transport of a positive charge and transporting it from the anode. An “electron transport material,” is another type of charge transport material, that can receive and facilitate the transport of a negative charge.

The term “charge injection material,” is used to mean a charge transport material located next to an electrode to receive charges and can be either an electron injection or hole injection material. Therefore a hole injection material is a hole transport material located next to an anode, and holes are injected into the hole injection material from the anode.

A electron injection material is an electron transport material located next to an cathode, and electrons are injection from the cathode to the electron injection material. A “blocking layer” is a charge transport layer includes a material to transport one charge, but blocks the transport of the other charge. A “hole blocking layer” transports electrons (an electron transport material), but blocks hole transport, and an “electron blocking layer” transport holes (a hole transport material), but blocks electron transport.

As used herein, the term “guest” is intended to mean a material, within a composition or layer. Such composition or layer includes a host material. The guest material in the composition or layer affects the targeted wavelength of radiation emission, reception, or filtering property of the composition or layer when compared to the radiation emission, reception, or filtering property of the composition or layer without the guest material.

As used herein the term “host” is intended to mean a material, within a composition or layer. Such a composition or layer includes a guest material, wherein the host material may affect the physical, chemical or electrical properties of a guest material and use of the host may provide an advantage or aid in the storage, shelf-life, or performance of the guest material, or use of a guest material in a particular deposition technique when making an organic electronic device, or in the use of the electronic device itself. A host material may have conductive properties, and includes materials that may create a solution, dispersion, emulsion or suspension including the guest and host materials. The host material may act as a hole transport material, electron transport material, or both, or neither.

As used herein, the term “liquid processing” includes any continuous or discontinuous method of depositing a material that is in the form of a liquid (which can be a solution, dispersion, emulsion or suspension). Liquid deposition techniques include, but are not limited to, continuous deposition techniques such as spin coating, gravure coating, curtain coating, dip coating, slot-die coating, casting, spray-coating, bar coating, roll coating, doctor blade coating and continuous nozzle coating; and discontinuous deposition techniques such as ink jet printing, gravure printing, and screen printing.

For purposes of this invention, a layer can be in the form as is when the material is originally deposited, or may be in a form after such deposited material that has undergone further processing; and materials may be elements, compounds or polymers (including copolymers) or a combination of elements, compounds or polymers in a number of combinations to form a composition.

As used herein, the term “photoactive material” is intended to mean a material that emits light when activated by an applied voltage (e.g., in a light-emitting diode or light-emitting electrochemical cell), a material that responds to radiant energy and generates a signal with or without an applied bias voltage (e.g., in a photodetector), or a material that converts radiation into an electrical signal. Such materials can exhibit electroluminenscence, photoluminescence, and/or photosensitivity. Such materials can be polymers (including co-polymers), organic small molecules, and organic metallic compounds and mixtures thereof.

As used herein, the term “excited state energy Eₑₓ” of the photoactive material is defined as highest energy peak of the luminescence spectrum as measured empricially by any number of known techniques (for luminescence materials), and for non-luminescence materials it is defined as the lowest energy peak absorption peak. The “excited state energy Eₑₓ” can also be determined by quantum mechanical calculations of the materials. For example, if the luminescence peak is at 520 nm, its energy is 2.38 eV.

As used herein, the terms “singlet” and “triplet” refer to the multiplicity of the electronic state that is descriptive of the degree of degeneracy in the absence of a perturbing magnetic field. For a singlet state, the electron spins are paired according to the Pauli exclusion principle (antiparallel). For a triplet state, on the other hand, the electron spins are unpaired (parallel).

Organic electronic devices are intended to mean a device including one or more organic semiconductive layers or materials wherein the device converts electrical energy into radiation (e.g., light-emitting diode display (passive or active matrix), light emitting diode, diode laser, or lighting panel), devices that convert radiation into electrical energy such as a photovoltaic cell or solar panel, and responds to radiant energy and generates a signal through electronic processes, such as photodectors (e.g., phototransistor, photoswitch, photoconductive cell, phototubes, and photoresistors), and IR detectors.

In one embodiment, the charge transport material is selected based on its having a triplet energy level higher than Eₑₓ by a predetermined amount. In one embodiment the predetermined amount is at least equal to or greater than 0.1 eV and in another embodiment, the predetermined amount is at least equal to or greater than 0.2 eV. In another embodiment, the charge transport material has a band gap that is equal to or larger than Eₑₓ. In one embodiment the electron transport material has a band gap that is equal to or larger than Eₑₓ. In one embodiment, the photoactive material includes a luminescent organometallic compound. In one embodiment the photoactive material includes a phosphorescent compound capable of emitting light via the triplet excitation state. In one embodiment, the phosphorescent compound is a transition metal organometallic compound.

In one embodiment, the photoactive material is selected from organic small molecule compounds having a molecular weight less than 2000.

As used herein, an “organometallic compound” is a compound having a metal-carbon bond. The organometallic compound may include metal atoms from Groups 3 through 15 of the Periodic Table and mixtures thereof. In one embodiment, the metal atoms are from Groups 8 through 11. In one embodiment, the metal atoms are of atomic number between 71 and 83, such as platinum, rhenium, osmium, gold, and iridium atoms. In one embodiment the organometallic compound is a fluorinated iridium compound.

Examples of suitable organometallic compounds include but are not limited to metal chelated oxinoid compounds, such as tris(8-hydroxyquinolato)aluminum (Alq3); cyclometalated iridium and platinum electroluminescent compounds such as those described in, for example, Petrov et al., Published PCT Application WO 02/02714, and LeCloux et al., Published PCT Application WO 03/040257, and organometallic complexes described in, for example, published applications U.S. 2001/0019782, EP 1191612, WO 02/15645, and EP 1191614; and mixtures thereof. Electroluminescent emissive layers comprising a charge carrying host material and a metal complex have been described in for example, U.S. Pat. No. 6,303,238, and PCT applications WO 00/70655, WO 01/41512 and WO04/062324. Electroluminescent emissive layers comprising a charge carrying host material and a phosphorescent platinum complex have been described in for example U.S. Pat. No. 6,303,238, Bradley et al., in Synth. Met. (2001), 116 (1-3), 379-383, and Campbell et al., in Phys. Rev. B, Vol. 65 085210.

In one embodiment, the electronic device further includes a charge injection layer located between the charge transport material and the electrode. In one embodiment, the organic device includes both electron injection and hole injection materials. In one embodiment, a charge injection material is selected to enhance charge injection from the electrode and also to balance electron-hole recombination in the photoactive layer.

In one embodiment, the electronic device further includes a charge blocking layer placed between the luminescent layer and the electrode. Examples of materials suitable for use in the hole injection materials are: copper phthalocyanine (CuPc), silicon oxy-nitride (SiOₓN_{y}), SiO2, polythiophene, polyaniline, organosilanes, doped aromatic amines, and fluorocarbons (CFₓ). Examples of materials suitable for use in the electron injection layer are: tris(8-hydroxyquinoline) aluminum (Alq₃), and quinoxalines.

In one embodiment, the HOMO of a hole blocking layer is lower than the HOMO of the luminescent layer so as to block the hole transport from the luminescent layer to the hole blocking layer. The LUMO of an electron blocking layer is higher than the LUMO of the luminescent layer so as to block the electron transport from the luminescent layer to the electron blocking layer. The energy of HOMO and LUMO is referenced to the vacuum level as energy zero. Examples of materials suitable for use in the hole blocking layer are: 4,7-diphenyl-1,10-phenanthroline (DPA), 1,3,5-tri(phenyl-2-benzimidazole)benzene (TPBI), and as bis(2-methyl-8-quinolinolato)(para-phenyl-phenolato)aluminum(III) (BAlQ). Examples of materials suitable for use in the electron blocking layer are N,N′-diphenyl-N,N′-(2-naphthyl)-(1,1′-phenyl)-4,4′-diamine (NPB) and bis[4-(N,N-diethylamino)-2-methylphenyl](4-methylphenyl)methane (MPMP).

Charge Transport Material

The transition from a singlet ground state to a singlet excited state is spin-allowed, leading to strong absorption. The luminescence from an excited singlet state to a ground singlet state is often called fluorescence, and is characterized by a high radiative rate (typically ˜10⁹ sec⁻¹ or larger). The transition from a singlet ground state to a triplet excited state is spin-forbidden, leading to weak absorption. The luminescence from an excited triplet state to a ground singlet state is often called phosphorescence, and is characterized by a low radiative rate (typically smaller than 10³ sec⁻¹). Due to the low radiative rate, phosphorescence for organic molecules is rarely observable at room temperature. (For more detailed discussions, see “Photophysics of Aromatic Molecules”, John B. Birks, John Weley & Sons Ltd., 1970; and “Modern Molecular Photochemistry”, Nicholas J. Turro, The Benjamin/Cumming Publishing Co., Inc., 1978).

For many organometallic molecules, the transition from the ground state to the excited state corresponds to the transfer of electron density from the metal atom to the surrounding ligands. The excited state reached by such transfer of electron density is herein referred to as the “MLCT state.” In such a system, the singlet and the triplet states are heavily mixed due to the strong spin-orbit coupling strength of the metal atom. The MLCT state often possesses properties that are intermediate between a singlet and a triplet state. For example, the radiative lifetime of an MLCT state is often in the microseconds or sub-microseconds range. This range, while being longer than the nanosecond radiative lifetime generally observed for a singlet state, is shorter than the milliseconds or seconds radiative lifetime of the triplet state. Sometimes, the electron density can be transferred from the ligand to the metal atom and such an excited state is herein referred to as the “Ligand to Metal Charge Transfer (LMCT) state.”

The luminescent lifetime of a MLCT state of an organometallic compound with high quantum efficiency is usually long, on the order of microseconds, compared to the typical nanoseconds to picoseconds lifetime of the singlet state. Because of this long lifetime, the electroluminescence efficiency of devices built with these materials is very sensitive to the nature of the electron transport and hole transport materials in the adjacent layers. In fact, if an electron transport layer is not used, the metal cathode can quench the electroluminescence very effectively.

In one embodiment, OLED devices can be fabricated by selecting charge transport materials based on their triplet state energy level. A good charge transport material has a triplet energy level that is higher than the energy level of an excited emitter molecule (referred to herein as an “exciton”). A material is not likely to be a good charge transport material if it has a triplet energy level that is comparable to or less than the exciton energy level of the luminescent material, regardless of its band gap size. Thus, according to one embodiment of the invention, selecting the charge transport material for a light emitting device entails comparing the exciton energy level of the luminescent material to the triplet energy level of each candidate charge transport material.

Determining the Triplet Energy Level

The charge transport material is selected based on its triplet energy level, which is difficult to measure with some of the conventional techniques. For example, absorption spectroscopy is one of the commonly used techniques for measuring the energy level of a singlet excited state. However, since the transition from a ground singlet state to an excited triplet state is spin-forbidden, the signal that results from this transition is weak. Due to the weak signal, it is difficult to measure the triplet energy based on absorption spectrum.

Phosphorescence spectroscopy is another commonly used technique for triplet energy level measurement. In some situations, however, it may be difficult to determine the triplet energy using phosphorescence spectroscopy because the transition from an excited triplet state to a ground singlet state (phosphorescence) is also spin-forbidden, and therefore shows a low radiative rate and weak luminance intensity. Although the weak phosphorescence signal can be enhanced by lowering the temperature in liquid nitrogen or helium, use of low temperature will also enhance the fluorescence signals from many impurities in the sample, making the definitive identification of the phosphorescence difficult.

A more generally useful technique for determining the triplet energy level is the energy transfer method described in A. P. Monkman, H. D. Burrows, L. J. Hartwell, L. E. Horsburgh, I. Hamblett, and S. Navaratnam, Phys. Rev. Lett., 86, 1358 (2001). In the energy transfer method, a series of molecules with known triplet energies are selected as the standard molecules. An energy transfer experiment between a standard molecule and a test molecule is performed to determine the relative triplet energy of the test molecule. For example, if the energy can be transferred from a standard molecule to the test molecule, it indicates that the triplet energy of the test molecule is comparable to or lower than the triplet energy of the standard molecule. This method can be further refined by the use of the Sandros equation (see K. Sandros, Acta. Chem. Scand. 18, 2355 (1964)), which relates the energy transfer rate constant, kₑ, to the energy difference, δE, in solution by the following equation:
kₑ=k_{d}(1+exp(−δE/kT))⁻¹ (1)
where k_{d} is the diffusion-controlled rate constant, k is the Boltzman constant, and T is the temperature in Kelvin. The accurate determination of the energy transfer rate constant, kₑ, can lead to the determination of the energy difference between the standard molecule and the test molecule, and therefore the triplet energy of the test molecule.

The energy transfer method can be further differentiated by the apparatus used to generate the triplet state of the standard molecules. For example, a laser flash photolysis method generates the triplet state with a laser beam, while a pulse radiolysis method generates the triplet state with an electron beam. Details about pulse radiolysis is provided in M. S. Matheson, L. M. Dorfman, “Pulse Radiolysis,” AEC./ACS Research Monographs in Radiation Chemistry, 1969. For pulse radiolysis, a triplet state is generated by a short electron pulse (nanosecond or picosecond duration) from an electron accelerator. The triplet state is detected by its absorption spectrum to the upper excited state using light pulse from a pulsed lamp (this is called the transient absorption method). The pulse radiolysis/transient absorption experiments were performed using the facility provided by the University of Notre Dame Radiation Lab.

Some of the standard molecules for pulse radiolysis are listed below with triplet energy levels:

| | |
|---|---|
| Benzophenone: | 2.975 eV |
| Biphenyl: | 2.836 eV |
| Naphthalene: | 2.63 eV |
| p-terphenyl: | 2.53 eV |
| benzil: | 2.32 eV |
| anthracene: | 1.84 eV |
| perylene: | 1.54 eV |

A different standard molecule is selected based on the type of test molecule.
Devices Using the Charge Transport Material

Also presented is an electronic device including a first electrode that generates positive charge carriers, a second electrode that generates negative charge carriers, and a photoactive layer between the two electrodes. There is a hole transport layer between the photoactive layer and the first electrode, and an electron transport layer between the photoactive layer and the second electrode. The photoactive layer contains a material that has an excited state energy Eₑₓ upon excitation by the positive and the negative charge carriers. One or both of the hole and electron transport layer materials have a triplet energy level that is higher than Eₑₓ.

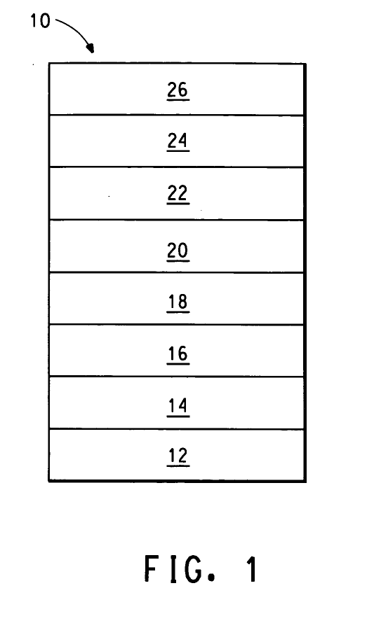

FIG. 1 is a side view of an exemplary electronic device 10 (an OLED) that is built using the triplet energy level-based selection method described above. The device 10 may include a substrate 12, an anode electrode 14, a hole injection layer 16 positioned on the anode electrode, a hole transport layer 18 on the hole injection layer, a light emitting layer 20 on the hole transport layer, an electron transport layer 22 on the light emitting layer, an electron injection layer 24 on the electron transport layer, and a cathode electrode 26 on the electron injection layer. The cathode electrode 26 typically includes LiF/Al or Mg/Ag layers. The anode electrode is preferably transparent or translucent and typically made of indium tin oxide (ITO).

The light emitting layer 20 may include one or more of various luminescent materials. In other devices, for example and depending on the application, the layer 20 may be a layer of photoactive material that responds to radiant energy and generates a signal with or without an applied bias voltage (such as in a photodetector). A non-exhaustive list of other devices having at least one photoactive layer includes photoconductive cells, photodectors, solar panels, photoresistors, photoswitches, phototransistors, phototubes, and photovoltaic cells.

In the OLED device, the light emitting layer 20 may be made of any suitable electroluminescent material, including, but not limited to, fluorescent dyes, fluorescent and phosphorescent small organic molecules, organometallic complexes, conjugated polymers (including copolymers), and mixtures thereof. In one embodiment, the luminescent material is an organometallic electroluminescent compound such as those previously described. These electroluminescent organometallic complexes (either alone or as mixtures) may be used alone or doped into charge-carrying hosts or non-charge carrying hosts.

Examples, but non-exhaustive list, of some materials which can be used in a hole injection or hole transport layer have been summarized in Kirk-Othmer Encyclopedia of Chemical Technology, Fourth Edition, Vol. 18, p. 837-860, 1996, by Y. Wang. Both hole transporting molecules and polymers can be used and include, for hole transporting molecules include, but are not limited to: N,N′-diphenyl-N,N′-bis(3-methylphenyl)-[1,1′-biphenyl]4,4′-diamine (TPD), 1,1-bis[(di-4-tolylamino) phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), N,N′-diphenyl-N,N′-(2-naphthyl)-(1,1′-phenyl)-4,4′-diamine (NPB), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), and porphyrinic compounds, such as copper phthalocyanine. Commonly used hole transporting polymers include, but are not limited to, polyvinylcarbazole, (phenylmethyl)polysilane, and polyaniline, and have been described, for example, in Hsu, Published PCT Applications WO 2004/029176, WO 2004/029128, and WO 2004/029133. It is also possible to obtain hole transporting polymers by doping hole transporting molecules such as those mentioned above into polymers such as polystyrene and polycarbonate.

Examples of materials which can be used in an electron injection or electron transport layer include, but are not limited to, metal chelated oxinoid compounds, such as bis(2-methyl-8-quinolinolato)(para-phenyl-phenolato)aluminum(II) (BAlq) and tris(8-hydroxyquinolato)aluminum (Alq₃); azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and mixtures thereof.

In one embodiment, the first triplet energy of the hole transport material in the hole transport is higher than the energy of the luminescent state of the emitter by a predetermined amount. In one embodiment, it is equal to or higher by about 0.1 eV. In one embodiment, it is equal to or higher by about 0.2 eV. In one embodiment, the first triplet energy of the electron transport material in the electron transport is higher than the energy of the luminescent state of the emitter. In one embodiment, it is equal to or higher by about 0.1 eV. In one embodiment, it is higher by about 0.2 eV. In one embodiment, the electronic device is an OLED, wherein, in addition to having a triplet energy level is equal to or higher than the energy of the luminescent state, the charge transport material has a low barrier for carrier injection from the electrodes, provides good electron or hole mobility, and is capable of forming good quality thin film.

Charge transport material may be selected based only on triplet energy levels or based on triplet energy levels along with other criteria. For example, the triplet energy level-based selection method may be combined with the band gap-based selection method described in Baldo et al. In this method, the charge transport material may be selected to have a triplet energy level that is substantially higher than the excited energy of the luminescent material and have a band gap that is substantially larger than the excited energy of the luminescent material. Furthermore, the correlation between the charge transport layer's triplet energy level and the exciton energy of the luminescent material can be used for other purposes not specifically described herein, such as selection of the luminescent material. Where the charge transport material is predetermined, the photoactive material may be selected based on its having an exciton energy level that is substantially lower than the triplet energy level of the charge transport material.

As used herein, the term “band gap,” refers to the difference between the energy level of the lowest unoccupied molecular orbital (LUMO) and the highest occupied molecular orbital (HOMO) of a material. Usually, the band gap can be obtained by measuring the absorption spectrum of a film. The HOMO is the energy level of the highest molecular orbital where electrons are filled. The HOMO level of a material can be measured with photoelectron spectroscopy or estimated by measuring the oxidation potential of a molecule in solution. The “Lowest Unoccupied Molecular Orbital LUMO is the energy level of the lowest unoccupied molecular orbital. The LUMO level of a material can be measured with inverse photoelectron spectroscopy.

In one embodiment, the thickness of the electrode is in the range of 200-10000 Å, and in another embodiment in the range of from 300-5000 Å. In one embodiment the electrode is an anode between 500-5000 Å, and in another embodiment, it is 1000-2000 Å. In one embodiment, the electrode is a cathode between 200-10000 Å, and in another embodiment, it is between 300-5000 Å. In one embodiment, the photoactive layer is between 10-2000 Å, and in another embodiment, in the range of 100-1000 Å. In one embodiment, the hole transport layer is between 50-2000 Å, and in another embodiment, it is 200-1000 Å. In one embodiment, the electron transport layer is between 50-2000 Å, and in another embodiment, it is 200-1000 Å.

In one embodiment the charge injection layer is between 50-2000 Å, and in another embodiment it is 200-1000 Å. In one embodiment, the blocking layer is between 50-2000 Å, and in another embodiment, it is between 200-1000 Å.

The various layers of electrode, charge transport layers, injection layers, photoactive layers, and blocking layers can be deposited on the device substrate or work piece in manufacture via any number of techniques including vapor deposition (thermal and chemical), thermal transfer, and liquid processing techniques.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present). Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Group numbers corresponding to columns within the periodic table of the elements use the “New Notation” convention as seen in the CRC Handbook of Chemistry and Physics, 81^{st} Edition (2000).

The new method will be further described by reference to the following non-limiting examples.

### EXAMPLES

The following examples illustrate certain features and advantages of the present invention. They are intended to be illustrative of the invention, but not limiting. All percentages are by weight, unless otherwise indicated.

### Example 1

This example provides the triplet energy levels of different electron and hole transport materials as determined by pulse radiolysis/transient absorption method described above, and shows that there is incomplete correlation between triplet energy level and band gap size. Toluene was used as the solvent.

Table I shows the HOMO-LUMO gap (the bandgap) and the triplet energy levels of the different transport materials. Only the lower limit is listed for MPMP and only the upper limit is listed for QNX-64. The HOMO-LUMO gap of these materials are obtained by measuring the absorption edge of the material in toluene solvent.

TABLE I
Triplet energy and HOMO-LUMO gap of a series of
electron and hole transport materials

| | HOMO | LUMO level, | HOMO-LUMO | Triplet energy, |
|---|---|---|---|---|
| Molecules | level, eV | eV | gap, eV | eV |
| MPMP | 5.53 | 1.88 | 3.65 | >2.95 |
| NPB | 5.61 | 2.55 | 3.06 | 2.8 |
| CPB | 5.79 | 2.39 | 3.4 | 2.6 |
| QNX-34 | 6.5 | 3.24 | 3.26 | 2.73 |
| QNX-64 | 6.57 | 3.54 | 3.03 | <2.53 |

The molecular structures of these materials are as follows:

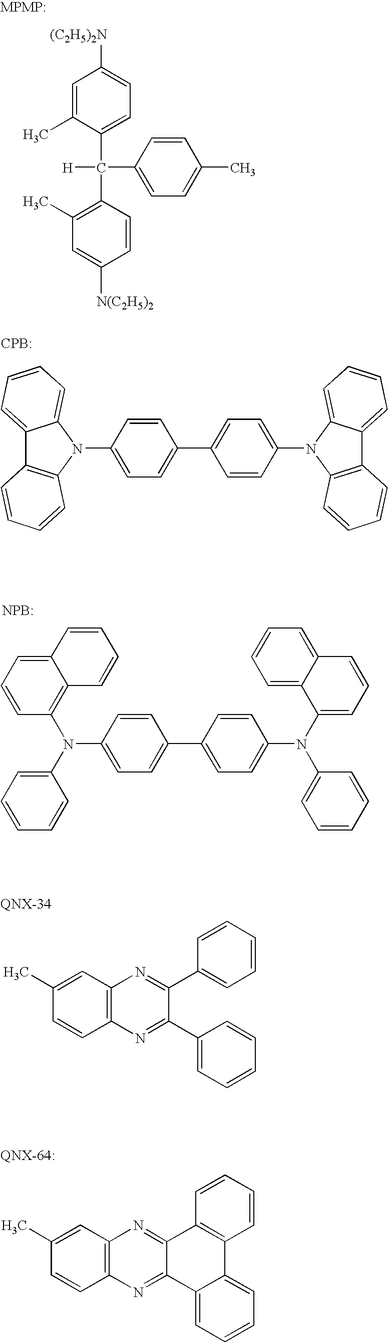

The data indicates that there is incomplete correlation between the band gap and the triplet energy level. For example, as the triplet energy level decreased in going from MPMP to NPB and from QNX-34 to QNX-64, so did the band gap. However, in going from NPB to CPB or CPB to QNX-34, the band gap decreased when the triplet energy level increased, and vice versa.

### Example 2

This example illustrates the effect of charge transport material triplet energy level on device efficiency.

Thin film OLED devices including a hole transport layer (HT layer), electroluminescent layer (EL layer) and at least one electron transport layer (ET layer) were fabricated using the well known thermal evaporation technique. An Angstrom Engineering evaporator with cryopump was used to deposit the layers. The base vacuum for all of the thin film deposition was in the range of 10⁻⁶ torr. The deposition chamber was capable of continuously depositing a plurality of films while maintaining the vacuum.

Patterned indium tin oxide (ITO) coated glass substrates from Thin Film Devices, Inc. was used to form anode electrodes. These ITO substrates are based on Corning 1737 glass coated with 1400 Å ITO coating, with sheet resistance of 30 ohms/square and 80% light transmission. The patterned ITO substrates were then cleaned ultrasonically in aqueous detergent solution. The substrates were then rinsed with distilled water, followed by isopropanol, and then degreased in toluene vapor for −3 hours.

The cleaned, patterned ITO substrate was then loaded into the vacuum chamber and the chamber was pumped down to 10⁻⁶ torr. The substrate was then further cleaned using an oxygen plasma for about 5-10 minutes. After cleaning, multiple layers of thin films were deposited sequentially onto the substrate by thermal evaporation. Finally, patterned metal electrodes of Al were deposited through a mask. The thickness of the film was measured during deposition using a quartz crystal monitor (Sycon STC-200). All film thickness reported in the Examples are nominal, calculated assuming the density of the material deposited to be one. The completed OLED device was then taken out of the vacuum chamber and characterized immediately without encapsulation.

The OLED samples were characterized by measuring their (1) current-voltage (I-V) curves, (2) electroluminescence radiance versus voltage, and (3) electroluminescence spectra versus voltage. The I-V curves of an OLED sample were measured with a Keithley Source-Measurement Unit Model 237. The electroluminescence radiance (in the unit of cd/m²) vs. voltage was measured with a Minolta LS-110 luminescence meter, while the voltage was scanned using the Keithley SMU. The electroluminescence spectrum was obtained by collecting light with a pair of lenses through an electronic shutter dispersed through a spectrograph and measured with a diode array detector. All three measurements were performed at the same time and controlled by a computer. The device efficiency (cd/A) at certain voltage is determined by dividing the electroluminescence radiance of the OLED by the current density needed to run the device.

Table II provides the device configurations used in examples. Generally, the hole transport layer had a thickness of about 300-600 Å, the electroluminescent layer had a thickness of 380-450 Å, and the electron transport layer had a thickness of about 400-500 Å including both the electron transport layer and the electron injection layer. The type of material included in each layer is specified in Table II.

TABLE II
Device configurations of OLED devices fabricated in the examples.
HT: hole transport; EL: electroluminance; ET: electron transport.

| | HT layer | EL layer | ET layer | cathode |
|---|---|---|---|---|
| Sample | Thickness, Å | thickness, Å | thickness, Å | thickness, Å |
| 1 | MPMP, | G100, | DPA/AlQ, | LiF/Al, |
| | 501 | 402 | 101/301 | 5/250 |
| 2 | CPB, | G100, | DPA/AlQ, | LiF/Al, |
| | 304 | 404 | 102/301 | 10/452 |
| 3 | NPB, | G100, | DPA/AlQ, | LiF/Al, |
| | 302 | 404 | 104/303 | 10/503 |
| 4 | MPMP | B100, | DPA/AlQ | LiF/Al |
| | 303 | 402 | 102/303 | 10/453 |
| 5 | NPB | B100 | DPA/AlQ | LiF/Al |
| | 302 | 404 | 104/305 | 10/505 |
| 6 | MPMP, | G100, | QNX-34/AlQ, | LIF/Al, |
| | 500 | 410 | 108/301 | 5/352 |
| 7 | MPMP, | G100, | QNX-64/AlQ, | LIF/Al, |
| | 502 | 402 | 102/303 | 5/497 |

The molecular structures of the materials used for device fabrication are as follows:

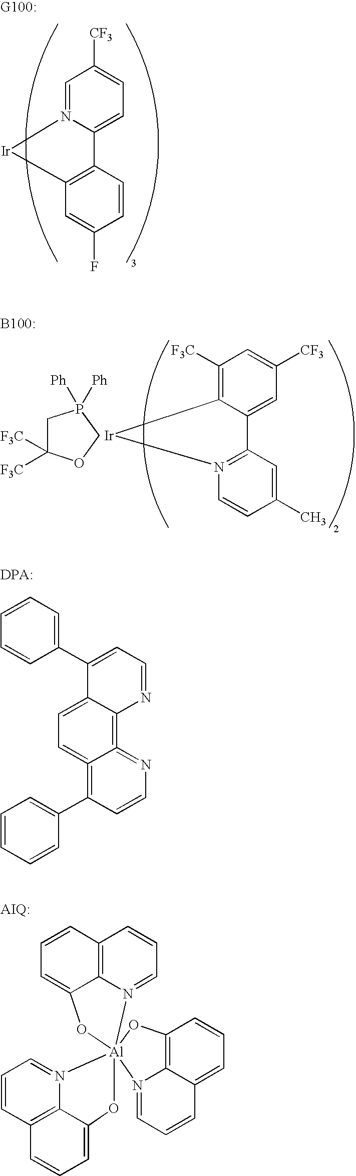

Table III shows the correlation between device efficiency and triplet energy of the transport material by providing more data about the Samples 1-7 of Table II. The exciton energy of the G100 emitter as neat film is 2.38 eV and 2.46 eV in toluene. The exciton energy of B100 emitter as neat film is 2.6 eV and 2.6 eV in toluene. As is well known, these exciton energy values may change if measured in a different state than toluene, for example in solid state.

TABLE III
Correlation between the device efficiency and the triplet
energy of the charge transport material.

| | | Peak | |
|---|---|---|---|
| | layer compositn. | efficiency | Triplet energy |
| Sample | (from Table II) | [cd/A] | [eV] |
| 1 | MPMP/G100/DPA | 26 | of HTM >2.95 |
| 2 | CPB/G100/DPA | 15 | of HTM = 2.8 |
| 3 | NPB/G100/DPA | 0.8 | of HTM = 2.6 |
| 4 | MPMP/B100/DPA | 11 | of HTM >2.95 |
| 5 | NPB/B100/DPA | 0.15 | of HTM = 2.6 |
| 6 | MPMP/G100/QNX-34 | 21 | of ETM = 2.73 |
| 7 | MPMP/G100/QNX-64 | 14 | of ETM <2.53 |

Samples 1-3 in Table III show the effect of varying the triplet energy of the HTM on the device efficiency of a green emitter G100. The exciton energy of G100 was measured to be about 2.46 eV in toluene and about 2.38 eV in a neat film. Table I above shows that the HTMs in Samples 1, 2, and 3 have HOMO-LUMO gaps of 3.65 eV, 3.4 eV, and 3.06 eV, respectively, all of which are larger than the exciton energy of the electroluminescent layer. The observed effect on the device efficiency is substantial improvement and correlates well with the triplet energy of the HTM. As the triplet energy of the HTM is lowered to approach that of the exciton energy of the emitter, the device efficiency is reduced and is believed to be due to energy transfer quenching by the triplet state of the transport material.

Samples 4-5 in Table III show the effect of varying the triplet energy of the HTM on the device efficiency of a blue emitter B100. Both HTM's have HOMO-LUMO gaps much larger than the exciton energy of B100, which was measured to be about 2.6 eV in toluene and about 2.6 eV in neat film. The observed effect on the device efficiency is substantial improvement and correlates well with the triplet energy of the HTM. As the triplet energy of the HTM is lowered to approach that of the exciton energy of the emitter, the device efficiency is reduced and is believed to be due to energy transfer quenching by the triplet state of the transport material.

Samples 6-7 of Table III show the effect of varying the triplet energy of the ETM on the device efficiency of a green emitter G100. Both ETM's have HOMO-LUMO gaps much larger than the exciton energy of G100 (2.46 eV in toluene, 2.38 eV as neat film), which would suggest minimal effect on the device efficiency according to U.S. Pat. No. 6,097,147. The observed effect on the device efficiency is a substantial improvement, and correlates well with the triplet energy of the ETM. As the triplet energy of the ETM is lowered to approach that of the exciton energy of the emitter, the device efficiency is reduced and is believed to be due to energy transfer quenching by the triplet state of the transport material. The observed effect of ETM is relatively smaller than that of HTM. It is believed that this observation is the result of the electron hole recombination zone in G100 is closer to the HTM side than the ETM side.

### Example 3

This example illustrates, via photoluminescence quenching experiments, that when the triplet energy of the charge transport material is lower than the exciton energy of the luminescent material, the luminescence intensity of the emitter material is quenched. The data in this example is consistent with the data in Example 2, which suggest that charge transport molecules having a higher triplet energy level make more efficient light emitting devices.

The effect of the triplet energy of the transport material on the luminescence efficiency of an emitter can be demonstrated via the photoluminescence quenching experiment. The luminescence quenching of an excited molecule can be described as
A*+Q→X (1)
where A* represents the luminescent excited state of the emitter, Q is the quencher (in this case the transport molecule under study), and X is the product of the quenching reaction. The rate constant of the luminescence quenching, k_{q}, can be obtained by the well-known Stern-Volmer equation:
(I_{q}/I₀)−1=k_{q}τ₀[Q] (2)
where I_{q} represents the luminescence intensity of the emitter in the presence of the quencher, I₀ represents the intensity in the absence of the quencher, τ₀ is the luminescent excited state lifetime in the absence of the quencher, and [Q] is the concentration of the quencher. By plotting (I_{q}/I₀)−1 vs [Q], the slope of the straight line gives k_{q}τ₀, which is known as the Stern-Volmer quenching constant. If τ₀ is known, then one obtains the luminescence quenching rate constant, k_{q}.

Table IV shows a correlation between the triplet energy of the quenching molecule and the Stern-Volmer quenching constant k_{q}τ₀ as measured on a G100 emitter. The exciton energy of G100 is located at 2.46 eV. Thus, molecules with triplet energy lower than 2.46 eV are efficient quenchers, as indicated by large Stern-Volmer quenching constant k_{q}τ₀. Molecules with triplet energy higher than 2.46 eV show virtually no quenching, as indicated by small values of the Stern-Volmer quenching constant k_{q}τ₀.

TABLE IV
Correlation between Stern-Volmer quenching constant k_{q}τ₀ and the
triplet energy of a charge transport molecule on G100 photoluminescence.

| Quencher | Triplet energy, eV | k_{q}τ₀ |
|---|---|---|
| anthracene | 1.8400 | 5095.6 |
| benzanthracene | 2.0500 | 8693.0 |
| fluoranthene | 2.2900 | 6651.0 |
| p-terphenyl | 2.5200 | 3.4000 |
| naphthalene | 2.6300 | 2.6600 |
| m-terphenyl | 2.7900 | 1.9400 |
| dibenzothiophene | 2.9500 | 1.7000 |
| benzophenone | 2.9700 | 2.5000 |
| xanthene | 3.4300 | 1.9000 |

Table V shows a correlation between the triplet energy of the quenching molecule and the Stern-Volmer quenching constant k_{q}τ₀ as measured on a R100 (red) emitter. The R100 emitter used to obtain these values has the following structure:

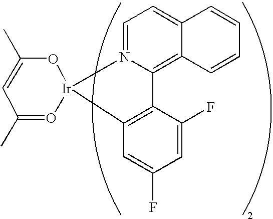

The exciton energy of R100 is about 2.06 eV in toluene. Molecules with triplet energy lower than 2.06 eV are efficient quencher, as indicated by large values of the Stern-Volmer quenching constant k_{q}τ₀. Molecules with triplet energy higher than 2.06 eV show virtually no quenching, as represented by small values of the Stern-Volmer quenching constant k_{q}τ₀.

This example demonstrates that charge transport molecules with triplet energies lower or comparable to the exciton energy of the emitter can quench the luminescence of the emitter. These molecules are generally not suitable as transport molecules in an OLED device.

TABLE V
Correlation between the Stern-Volmer quenching constant
k_{q}τ₀ and the triplet energy of a charge transport molecule
on R100 photoluminescence intensity.

| Quencher | Triplet energy, eV | k_{q}τ₀ |
|---|---|---|
| anthracene | 1.8400 | 11632 |
| benzanthracene | 2.0500 | 849.00 |
| fluoranthene | 2.2900 | 0.0000 |
| benzil | 2.3200 | 0.0000 |
| p-terphenyl | 2.5200 | 0.0000 |
| naphthalene | 2.6300 | 0.24000 |
| biphenyl | 2.9700 | 0.50000 |
| xanthone | 3.2100 | 0.079000 |

This example provides another way to demonstrate triplet energy-based selection method without building an actual device.

While the invention has been described in detail with reference to certain embodiments thereof, it will be understood that modifications and variations are within the spirit and scope of that which is described and claimed.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1. An electronic device comprising:
an electrode;
a layer that contains photoactive material, wherein an excited state of the photoactive material has an excitation energy Eₑₓ and wherein the photoactive material is either: (1) not a guest in a composition including a host material; or (2) is a guest in a composition including a host, and wherein an electronic transport material is not included in the composition; and
a charge transport layer, including a charge transport material, located between the electrode and the photoactive layer, wherein the charge transport material has a triplet energy level that is higher than Eₑₓ.

2. An electronic device comprising:
an electrode,
a layer that includes a photoactive material, wherein an excited state of the photoactive material has an excitation energy Eₑₓ and wherein the photoactive material is a guest in a composition including the photoactive material, a host, and an electron charge transport material; and,
at least one hole transport layer containing a hole transport material and at least one electron transport layer containing an electron transport material, wherein a hole transport material and an electron transport material in each layer, respectively, has a triplet energy level that is higher than Eₑₓ.

3. The device of claim 1, wherein the charge transport material is selected based on its having a triplet energy level higher than Eₑₓ by a predetermined amount.

4. The device of claim 2, wherein the hole transport material and electron transport material are selected based on its having a triplet energy level higher than Eₑₓ by a predetermined amount.

5. The device of claim 2, wherein the predetermined amount is at least equal to or greater than 0.1 eV.

6. The device of claim 1, wherein the predetermined amount is at least equal to or greater than 0.1 eV.

7. The device of claim 2, wherein the predetermined amount is at least equal to or greater than 0.2 eV.

8. The device of claim 1, wherein the predetermined amount is at least equal to or greater than 0.2 eV.

9. The device of claim 1 further comprising a charge injection layer located between the charge transport material and the cathode.

10. The device of claim 2 further comprising a charge injection layer located between the charge transport material and the cathode.

11. The device of claim 1, wherein the charge transport layer has a thickness of about 50-1000 Å.

12. The device of claim 2, wherein the charge transport layer has a thickness of about 50-1000 Å.

13. The device of claim 1, wherein the photoactive material is an organometallic compound.

14. The device of claim 2, wherein the photoactive material is an organometallic compound.

15. The device of claim 1, where the photoactive material has an Eₑₓ larger than 2.3 eV.

16. The device of claim 2, where the photoactive material has an Eₑₓ larger than 2.3 eV.

17. The device of claim 1 further comprising a hole injection layer located between the hole transport layer and and the anode.

18. The device of claim 2 further comprising a hole injection layer located between the hole transport layer and and the anode.

19. A device according to claim 1 that is selected from the group consisting of a light-emitting diode, a light-emitting diode display, a lighting panel, a photoconductive cell, a photodector, an IR detector, a solar panel, a photoresistor, a photoswitch, a phototransistor, a phototube, and a photovoltaic cell.

20. A device according to claim 2 that is selected from the group consisting of a light-emitting diode, a light-emitting diode display, a lighting panel, a photoconductive cell, a photodector, an IR detector, a solar panel, a photoresistor, a photoswitch, a phototransistor, a phototube, and a photovoltaic cell.
